(19) United States
(12) Patent Application Publication
(10) Pub. No.: US 2008/0035912 A1
(43) Pub. Date: Feb. 14, 2008

(54) Field-Effect Transistor, Method of Manufacturing the Same, and Electronic Device Using the Same

(75) Inventors: Takayuki Takeuchi, Osaka (JP); Takahiro Kawashima, Osaka (JP); Tohru Saitoh, Osaka (JP); Tomohiro Okuzawa, Osaka (JP); Yasuo Kitaoka, Osaka (JP)

Correspondence Address: HAMRE, SCHUMANN, MUELLER & LARSON P.C., P.O. BOX 2902-0902, MINNEAPOLIS, MN, 55402, US

(73) Assignee: MATSUSHITA ELECTRIC INDUSTRIAL CO., LTD., Osaka, JP (JP)

(21) Appl. No.: 10/599,658

(22) PCT Filed: Aug. 30, 2005
(86) PCT No.: PCT/JP05/15705

§ 371 Date: Oct. 4, 2006

(30) Foreign Application Priority Data
Aug. 31, 2004 (JP) 2004-251453

(51) Int. Cl. H01L 51/10; H01L 21/336

(52) U.S. Cl. 257/40; 438/99; 257/E51.006

(57) ABSTRACT

A field-effect transistor includes a semiconductor layer (14), a source electrode (15) and a drain electrode (16) electrically connected to the semiconductor layer (14), and a gate electrode (12) for applying an electric field to the semiconductor layer (14) between the source electrode (15) and the drain electrode (16). The semiconductor layer (14) contains an organic semiconductor material and a plurality of thin wires made of an inorganic semiconductor.

### TECHNICAL FIELD

The present invention relates to a field-effect transistor, a method of manufacturing the transistor, and an electronic device using the transistor.

### BACKGROUND ART

Field-effect transistors (hereinafter also referred to as “FETs”) are used widely in various electronic devices, such as active matrix-type displays. In such electronic devices, the use of plastic substrates makes lightweight and flexible devices possible. The use of plastic substrates, however, requires the formation of semiconductor layers at low temperatures.

A method of forming a semiconductor layer using semiconductor nanowires has been proposed as the method for forming a semiconductor layer of FETs at low temperatures. The method is described, for example, in Xiangfeng Duan et al., “High-performance thin-film transistors using semiconductor nanowires and nanoribbons,” Nature, Sep. 18, 2003, Vol. 425, pp. 274-278. The method also is described in U.S. Patent Application Publication No. 2005/0079659. The method also is described in Published PCT Application No. WO2004/032193.

The methods described in the above-mentioned publications, however, fail to achieve sufficient electrical contact between nanowires and electrodes and sufficient electrical contact between nanowires, and also cause large variations in the electrical contacts. Consequently, the FETs obtained by the above-described conventional methods have a problem of large variations in their performance, such as the threshold voltage.

### DISCLOSURE OF THE INVENTION

In view of the foregoing circumstances, it is an object of the present invention to provide a field-effect transistor that shows small variations in performance, and in particular, it is an object of the invention to provide a field-effect transistor that shows small variations in performance and that can be manufactured at low temperatures.

In order to accomplish the foregoing objects, the present invention provides a field effect transistor including a semiconductor layer, a source electrode and a drain electrode electrically connected to the semiconductor layer, a gate electrode for applying an electric field to the semiconductor layer, the semiconductor layer comprising an organic semiconductor material and a plurality of thin wires made of an inorganic semiconductor.

The present invention also provides an electronic device including a substrate and a transistor formed on the substrate, wherein the transistor is the foregoing field-effect transistor according to the invention.

The present invention also provides a method of manufacturing a field-effect transistor including a substrate, a semiconductor layer formed on the substrate, a source electrode and a drain electrode electrically connected to the semiconductor layer. The method includes the steps of: (i) growing on the substrate a plurality of thin wires made of an inorganic semiconductor; (ii) laying down the thin wires in a direction connecting the source electrode and the drain electrode; and (iii) impregnating space between the laid-down thin wires with an organic semiconductor material.

Utilizing the field-effect transistor according to the present invention can provide field-effect transistors with small variations in performance. Furthermore, the field-effect transistor according to the invention can be formed at a low temperature, and can therefore be formed even on a flexible substrate made of a polymer material. The electronic device according to the invention uses the field-effect transistor according to the invention and is therefore capable of having such characteristics as being lightweight, flexible, high shock resistance, and ease of manufacture.

### BRIEF DESCRIPTION OF THE DRAWINGS

FIGS. 1A to 1D are cross-sectional views schematically illustrating an example of a FET according to the present invention.

FIGS. 2A and 2B are cross-sectional views schematically illustrating another example of the FET according to the present invention.

FIGS. 3A and 3B are schematic views illustrating one example of the disposition of inorganic semiconductor thin wires in a semiconductor layer.

FIGS. 4A to 4H are schematic views illustrating one example of a method, according to the present invention, of manufacturing a FET.

FIGS. 5A to 5E are top views schematically illustrating another example of the method, according to the present invention, of manufacturing a FET.

FIG. 6 is a partially exploded perspective view schematically illustrating one example of an active matrix-type display according to the present invention.

FIG. 7 is a perspective view schematically illustrating the configuration of the driving circuit and its periphery.

FIG. 8 is a perspective view schematically illustrating one example of the configuration of a wireless ID tag.

FIG. 9 is a perspective view schematically illustrating one example of the configuration of a portable television.

FIG. 10 is a perspective view schematically illustrating one example of the configuration of a communication terminal.

FIG. 11 is a perspective view schematically illustrating one example of the configuration of a portable medical device.

### BEST MODE FOR CARRYING OUT THE INVENTION

Hereinbelow, embodiments of the present invention will be described. The field-effect transistor (thin film transistor) according to the present invention is a field-effect transistor furnished with a semiconductor layer, a source electrode and a drain electrode electrically connected to the semiconductor layer, and a gate electrode for applying an electric field to the semiconductor layer, wherein the semiconductor layer contains an organic semiconductor material and a plurality of thin wires made of an inorganic semiconductor. The gate electrode is an electrode for applying an electric field to at least a portion of the semiconductor layer that exists between the source electrode and the drain electrode. The details of the semiconductor layer containing an organic semiconductor material and thin wires made of an inorganic semiconductor (inorganic semiconductor thin wires) will be discussed later.

The field-effect transistor of the present invention makes it possible to reduce variations in electrical contact between the semiconductor layer and the electrodes, and variations in electrical contact between the inorganic semiconductor thin wires. Therefore, the field-effect transistors with small variations in performance and fast response speed will be obtained. In particular, the conventional field-effect transistor that uses inorganic semiconductor thin wires has caused a problem of large variations in electrical contact between electrodes and semiconductor thin wires, but the present invention can reduce the variations easily. Moreover, in the field-effect transistor of the present invention, the semiconductor layer can be formed at a low temperature, and therefore, it is possible to form the field-effect transistor on a flexible substrate made of a polymer material or the like. The semiconductor layer of the field-effect transistor according to the invention contains the inorganic semiconductor thin wires and therefore shows higher mobility than the semiconductor layer formed only of an organic semiconductor material. Furthermore, because the semiconductor layer of the field-effect transistor of the present invention contains the inorganic semiconductor thin wires, it is possible to form an n-type semiconductor layer, which is difficult to be formed only of an organic semiconductor material.

In the field-effect transistor of the present invention, the inorganic semiconductor thin wires may be connected to at least one electrode selected from the group consisting of the source electrode and the drain electrode via the organic semiconductor material. This configuration can reduce the contact resistance between the inorganic semiconductor thin wires and the electrode(s), and moreover can reduce variations in the contact resistance.

In the field-effect transistor of the present invention, both the organic semiconductor material and the thin wires may function as a p-type semiconductor. In addition, both of them may function as an n-type semiconductor.

The inorganic semiconductor thin wires and the organic semiconductor material are selected depending on the required characteristics of the semiconductor layer. The inorganic semiconductor thin wires may be at least one selected from the group consisting of Si thin wires and Ge thin wires. The organic semiconductor material may be at least one selected from the group consisting of poly(3-alkylthiophene) and poly(9,9′-dioctylfluorene-co-bithiophene). Examples of the combination of the inorganic semiconductor thin wires and the organic semiconductor material include: Si thin wires/poly(3-alkylthiophene); Si thin wires/poly(9,9′-dioctylfluorene-co-bithiophene) Ge thin wires/poly(3-alkylthiophene) and Ge thin wires/poly(9,9′-dioctylfluorene-co-bithiophene). When these materials are employed, it is preferable that the materials used for the source electrode and the drain electrode be indium-tin oxide (ITO), nickel, gold, polyethylenedioxythiophene (PEDOT), and the like.

In the field-effect transistor of the present invention, the semiconductor layer may be formed in stripes parallel to a direction connecting the source electrode and the drain electrode. In other words, the semiconductor layer may be composed of a plurality of band-shaped semiconductor layers disposed in stripes. These band-shaped semiconductor layers are formed so as to extend in the direction connecting the source electrode and the drain electrode. These semiconductor layers may be formed by, for example, forming a liquid repellent film having stripe-shaped through holes and forming a semiconductor layer in the through-hole portions. Examples of the liquid repellent film that may be used include a water-repellent monomolecular film and an oil-repellent monomolecular film. Forming the semiconductor layer in this method makes it possible to orient the inorganic semiconductor thin wires within the semiconductor layer in the direction connecting the source electrode and the drain electrode.

In the field-effect transistor of the present invention, the average diameter of the thin wires (inorganic semiconductor thin wires) may be 100 nm or less. Here, the term “average diameter of thin wires” means an average diameter of 100 thin wires arbitrarily selected from the semiconductor thin wires in the semiconductor layer observed by a scanning microscope.

In the field-effect transistor of the present invention, the thin wires (inorganic semiconductor thin wires) may be oriented in a direction connecting the source electrode and the drain electrode. This configuration makes it possible to increase the effective mobility of the carriers flowing between the source electrode and the drain electrode, and thus to attain a field-effect transistor with a fast response speed.

In the field-effect transistor of the present invention, the thin wires (inorganic semiconductor thin wires) may be grown from at least one electrode selected from the source electrode and the drain electrode. This configuration can reduce the contact resistance between the electrode(s) and the inorganic semiconductor thin wires.

The electronic device according to the present invention is an electronic device including a substrate, and a transistor formed on the substrate, wherein the transistor is the above-described field-effect transistor according to the present invention.

In the electronic device of the present invention, the substrate may be made of a polymer material. This configuration can provide a lightweight and flexible electronic device.

The electronic device of the present invention may be an active matrix-type display. In addition, the electronic device of the present invention may be a wireless ID tag. In addition, the electronic device of the present invention may be a portable device.

A method according to the present invention for manufacturing a field-effect transistor includes a step (i) of growing on a substrate a plurality of thin wires made of an inorganic semiconductor. In the step (i), the inorganic semiconductor thin wires are grown in a direction substantially perpendicular to a surface of the substrate. The inorganic semiconductor thin wires may be grown by known methods. Next, the inorganic semiconductor thin wires are laid down in a direction connecting the source electrode and the drain electrode (step (ii)). Next, the space between the laid-down inorganic semiconductor thin wires is impregnated with an organic semiconductor material (step (iii)). In this manner, the semiconductor layer containing the inorganic semiconductor thin wires and the organic semiconductor material is formed.

Hereinbelow, examples of embodiments of the present invention are described. It should be noted, however, that the present invention is not limited to the following embodiments. In the drawings that are referred to in the following, hatching may be omitted for some parts.

### Embodiment 1

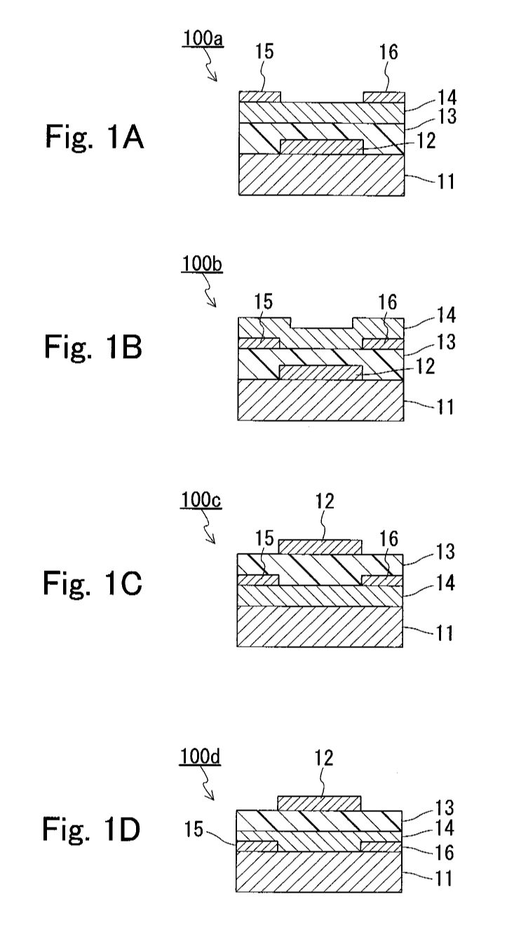

In the following, an example of the FET according to the present invention is described. FIGS. 1A to 1D are cross-sectional views schematically illustrating representative examples of the FET according to the present invention. As illustrated in FIGS. 1A to 1D, there exist various configurations of the FET according to the present invention. Each of FETs 100a to 100d respectively shown in FIGS. 1A to 1D is provided with a substrate 11, a gate electrode 12, a gate insulating layer 13, a semiconductor layer 14, a source electrode 15, and a drain electrode 16. A portion of the semiconductor layer 14 functions as a channel region. Although the source electrode 15 and the drain electrode 16 are directly in contact with the semiconductor layer 14 generally, a layer for reducing the contact resistance may be disposed at the interface between the source electrode 15 and the drain electrode 16.

The gate electrode 12 generally opposes the semiconductor layer 14 across the gate insulating layer 13. The gate electrode 12 is an electrode for applying an electric field to at least the channel region, in other words, a portion of the semiconductor layer 14 between the source electrode 15 and the drain electrode 16. The electric field applied to the semiconductor layer 14 by the gate electrode 12 controls electric current flowing between the source electrode 15 and the drain electrode 16. The semiconductor layer 14 contains the above-described inorganic semiconductor thin wires (hereinafter also referred to as “semiconductor thin wires” or “nanowires”) and the above-described organic semiconductor material. Although the semiconductor layer 14 is typically composed only of the semiconductor thin wires and the organic semiconductor material, it may contain other materials as necessary.

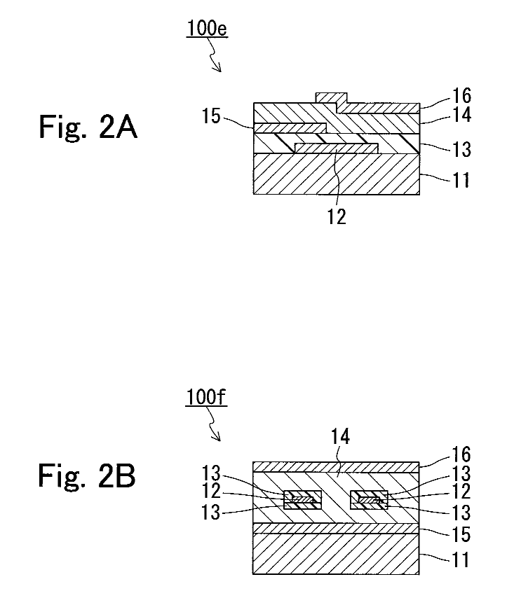

The FET according to the present invention may be a vertical type FET, as illustrated in FIGS. 2A and 2B. In each of a FET 100e shown in FIG. 2A and a FET 100f shown in FIG. 2B, the source electrode 15 and the drain electrode 16 oppose each other with the semiconductor layer 14 interposed therebetween along the film thickness direction.

The materials for the substrate 11 are not particularly restricted. Lightweight and flexible FETs can be obtained by using as the substrate 11 a film made of a polymer material, such as a film made of polyethylene terephthalate (PET), polyethylenenaphthalate (PEN), or polyimide. It should be noted, however, that it is also possible to use a substrate made of an inorganic material, such as a glass substrate or a silicon substrate.

The gate electrode 12 can be formed of conductive materials; for example, it may be formed of metal such as Ni or conductive polymer materials. The gate electrode 12 can be formed by known methods. For example, the gate electrode 12 may be formed by mask evaporation or a photolithography-etching process. The gate electrode 12 also may be formed by printing a conductive polymer by an ink jet method.

The source electrode 15 and the drain electrode 16 can be formed of conductive materials; for example, they may be formed of metals such as Au, Ag, Cu, Al, Pt, and Pd, or conductive polymer materials. The source electrode 15 and the drain electrode 16 can be formed by known methods. These electrodes may be formed by mask evaporation. These electrodes may be made by forming a film of a conductive material by a sputtering method or a CVD method and patterning the formed film by a photolithography-etching process. The etching may be conducted by, for example, anisotropic dry etching. The resist film may be removed by, for example, oxygen-based plasma etching. The electrodes may be formed by printing a conductive polymer using an ink jet method.

The gate insulating layer 13 can be formed of insulative materials, including organic materials such as polyvinyl alcohol, polyvinyl phenol, and polyimide, and insulative inorganic oxides such as SiO₂ and Ta₂O₅. The gate insulating layer 13 can be formed by known methods, such as a spin coating method and an evaporation method.

The semiconductor layer 14 is made of a mixture containing an organic semiconductor material and a plurality of inorganic semiconductor thin wires. Because the organic semiconductor material is disposed between the plurality of inorganic semiconductor thin wires, variations in contact resistance between the inorganic semiconductor thin wires can be reduced. Also, because the organic semiconductor material is disposed between the inorganic semiconductor thin wires and the electrodes, variations in contact resistance between the inorganic semiconductor thin wires and the electrodes can be reduced likewise.

Although the semiconductor layer 14 may be made only of the organic semiconductor material and the inorganic semiconductor thin wires, it may contain other substances as long as the advantageous effects of the present invention can be attained. Generally, the total of the organic semiconductor material and the inorganic semiconductor thin wires accounts for 90 weight % or more of the semiconductor layer 14 (for example, 99 weight % or more). The mixing ratio of the organic semiconductor material and the inorganic semiconductor thin wires is not particularly restricted, and may be selected depending on the materials used and the required characteristics of the FET. In one example, the weight ratio of the organic semiconductor material and the inorganic semiconductor thin wires may be in the range of [organic semiconductor material]: [inorganic semiconductor thin wires]=about 20:1 to about 1:2 (for example, in the range of 2:1 to 1:2).

The organic semiconductor material is an organic material that shows semiconductor properties, and it is possible to use known organic molecules. The organic semiconductor material may contain a dopant. It is preferable that the organic semiconductor material be organic molecules that can be dispersed or dissolved in a solvent. Examples of the preferable organic molecules include poly(3-alkylthiophene), poly(9,9′-dioctylfluorene-co-bithiophene), polyacethylene, and poly(2,5-thienylenevinylene). It is preferable that the organic semiconductor material have high solubility with the solvent, from the viewpoint of being blended with the inorganic semiconductor thin wires uniformly. In addition, from the viewpoint of obtaining higher transistor performance, it is preferable that the organic semiconductor material be such a material that a high-performance semiconductor layer can be formed of that material alone. Moreover, from the viewpoint of relaying electric charge between the electrodes and the inorganic semiconductor thin wires, or between the inorganic semiconductor thin wires, it is preferable that the organic semiconductor material be a material that shows a low contact resistance with the electrode material or the inorganic semiconductor thin wires to be used.

The inorganic semiconductor thin wires can be formed of a material that shows semiconductor properties in a bulk state; for example, it can be formed of semiconductors such as silicon and germanium. These semiconductors may be doped with impurities (dopants); for example, silicon doped with phosphorus (P) or germanium doped with boron (B) may be used. The doping may be carried out by adding the dopant to the source material when growing the thin wires, or by ion-implanting the dopant into the formed thin wires.

The dimensions of the inorganic semiconductor thin wires vary depending on the manufacturing method and manufacturing conditions. The average diameter of the inorganic semiconductor thin wires is generally about 20 nm or less, and may be within the range of 1 nm to 100 nm, for example. Although not particularly limited, the average length of the inorganic semiconductor thin wires is, for example, about 0.1 μm to about 50 μm, and is generally about 1 μm to about 10 μm. Here, the term “average length of semiconductor thin wires” means an average length of 100 thin wires arbitrarily selected from the semiconductor thin wires in the semiconductor layer observed by a scanning microscope.

The inorganic semiconductor thin wires can be formed by various methods including known methods. Example of the method of forming inorganic semiconductor thin wires are described in, for example, the publications mentioned in the section of Background Art hereinabove. The method of forming inorganic semiconductor thin wires also is described in Science, Vol. 279, (1998), pp. 208-211. The method also is described in Journal of Crystal Growth, Vol. 254 (2003) pp. 14-22. The method also is described in Applied Physics Letters, Vol. 84, (2004), pp. 4176-4178.

Thin wires (nanowires) with controlled diameters can be grown from a catalytic metal by the VLS (Vapor-Liquid-Solid) growth mechanism. The growth of thin wires can be conducted by, for example, vapor phase growth methods such as a CVD method. When Si nanowires are to be grown, for example, a silane gas (monosilane) or a disilane gas preferably should be supplied. When Ge nanowires are to be grown, for example, a germane gas preferably should be supplied.

Although there are no particular restrictions to the catalytic metal, it is possible to use transition metals, such as gold, iron, cobalt, and nickel, or alloys thereof. Although the catalytic metal is generally used in the form of fine particles, it may be used in other forms. The formation method for the catalytic metal is not particularly restricted, and the fine particles may be formed, for example, by depositing a catalytic metal on a growth substrate and causing the metal to aggregate by heat-treating. Alternatively, catalyst fine particles may be disposed at predetermined positions by applying a solution in which fine particles of a catalytic metal are dispersed onto the surface on which thin wires are to be grown, followed by drying. This method is preferable in that the catalyst fine particles can be disposed at a low temperature.

In the following, one example of the manufacturing method of the inorganic semiconductor thin wires is described. First, catalyst fine particles are disposed on a substrate. The catalyst fine particles can be disposed on the substrate by spin coating a Au colloidal solution in which the catalyst fine particles are dispersed in a solvent onto the substrate, and thereafter removing the solvent. Next, nanowires are grown from the catalytic metal by a CVD method (which may be an ordinary LP-CVD method). The nanowires can be grown at a growth temperature of 450° C. for a growth duration of about 1 hour, using silane (gas flow rate: about 50 sccm) as the growth gas.

The semiconductor layer 14 may be formed by various methods. For example, the semiconductor layer 14 may be formed by applying a solution containing inorganic semiconductor thin wires, an organic semiconductor material, and a solvent (or a dispersion medium, likewise hereinafter) to form a film, and thereafter removing the solvent. In this case, usable examples of the solvent include, but are not particularly limited to, chloroform, toluene, xylene, and mesitylene.

Alternatively, the semiconductor layer 14 may be formed by forming a film made of inorganic semiconductor thin wires and thereafter supplying an organic semiconductor material to the surface of the film. The organic semiconductor material supplied to the surface of the film made of the semiconductor thin wires is impregnated into the film, and thus, the semiconductor layer 14 can be formed that is a hybrid of the semiconductor thin wires and the organic semiconductor material. The film made of the inorganic semiconductor thin wires can be formed by forming a coating film by applying a solution containing inorganic semiconductor thin wires dispersed in a solvent to form a coating film and thereafter removing the solvent. Alternatively, the inorganic semiconductor thin wires may be grown from the substrate. In this case, a film containing a plurality of semiconductor thin wires oriented in a specific direction can be formed by laying down the plurality of grown inorganic semiconductor thin wires in one direction. Alternatively, the inorganic semiconductor thin wires may be grown from the surface(s) of the source electrode 15 and/or the drain electrode 16. In this method, by exposing only a predetermined portion (for example, a side face) of the electrode using a mask or the like, the semiconductor thin wires can be grown only from that portion. In this way, it becomes possible to grow the semiconductor thin wires from one of the electrodes toward the other electrode. The organic semiconductor material may be supplied by an evaporation method or by applying a solution containing the organic semiconductor material.

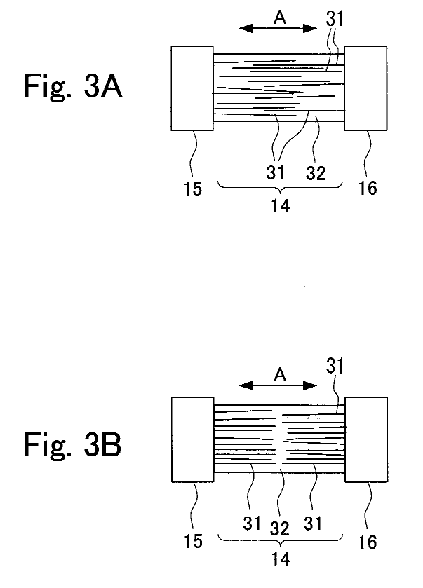

FIG. 3 schematically illustrates a preferable example of orientation of the inorganic semiconductor thin wires in the semiconductor layer 14. The semiconductor layer 14 is made of a mixture of inorganic semiconductor thin wires 31 and an organic semiconductor material 32. In the example of FIG. 3A, the inorganic semiconductor thin wires 31 are oriented in the direction substantially parallel to the direction A connecting the source electrode 15 and the drain electrode 16. An example of the method for attaining such an orientation is as follows; the inorganic semiconductor thin wires 31 are grown while the electrodes are being masked so that only the opposing side faces are exposed among the side faces of the source electrode 15 and the side faces of the drain electrode 16. In the example of FIG. 3B, the inorganic semiconductor thin wires 31 are grown from surfaces of the source electrode 15 and the drain electrode 16 toward the respective opposing electrodes, in other words, substantially parallel to the direction A. According to these configurations, a channel region with higher mobility can be formed. It should be noted that in the example of FIG. 3B, the inorganic semiconductor thin wires 31 may be grown from only one of the source electrode 15 or the drain electrode 16.

It should be noted that the configurations of the FET are not particularly restricted as long as the advantageous effects of the present invention can be attained. In the following, the FET 100b shown in FIG. 1B and the FET 100d shown in FIG. 1D are discussed as examples.

In the FET 100b shown in FIG. 1B, the gate electrode 12 is formed on one major surface of the substrate 11, and the gate insulating layer 13 is formed so as to cover the gate electrode 12. The source electrode 15 and the drain electrode 16 are formed on the gate insulating layer 13 so as to be spaced apart from each other. The semiconductor layer 14 is formed so as to cover the source electrode 15, the drain electrode 16, and the exposed surface of the gate insulating layer 13. The semiconductor layer 14 is a composite of the inorganic semiconductor thin wires and the organic semiconductor material. Thus, the gate electrode 12, the gate insulating layer 13, the two electrodes, and the semiconductor layer 14 are stacked on top of the substrate 11 of the FET 100b.

In the FET 100d shown in FIG. 1D, the source electrode 15 and the drain electrode 16 are formed on one major surface of the substrate 11 so as to be spaced apart from each other at a certain distance. It should be noted that an insulating layer made of, for example, SiO₂ is formed on the surface of the substrate 11, as necessary. The semiconductor layer 14 is formed so as to cover the two electrodes and the exposed surface of the substrate 11. The gate insulating layer 13 is formed over the semiconductor layer 14. The gate electrode 12 is formed on top of the gate insulating layer 13 and at least at a position corresponding to a region between the source electrode 15 and the drain electrode 16. Thus, the two electrodes, the semiconductor layer 14, the gate insulating layer 13, and the gate electrode 12 are stacked on top of the substrate 11 of the FET 100d.

In the FET according to the present invention, a gap L between the source electrode 15 and the drain electrode 16 may be about 2 to 10 times the average length of the semiconductor inorganic thin wires. When the gap L is equal to or greater than about 2 times the average length of the semiconductor inorganic thin wires, carriers that travel from the source electrode 15 to the drain electrode 16 need to pass through two or more thin wires. The FET according to the present invention can achieve high mobility even in such a case because the gap between the thin wires is connected by the organic semiconductor material.

In the following, practicable examples of the method of manufacturing a FET according to the present invention are described. It should be understood that the materials and formation methods for various components described below are merely illustrative examples, and the present invention is not limited to the following examples.

### [First Manufacturing Method]

In the following, one example of the manufacturing method of the FET 100b shown in FIG. 1B is described. First, the gate electrode 12 (thickness of 100 nm, for example) made of Ni is formed on the substrate 11 (thickness of 100 μm, for example) made of polyethylene terephthalate (PET) by mask evaporation. Next, an aqueous solution of polyvinyl alcohol is coated thereon by spin coating, followed by drying, to form the gate insulating layer 13 (thickness of 500 nm, for example). Next, the source electrode 15 and the drain electrode 16 (both thickness of 100 nm, for example) made of Au are formed on the gate insulating layer 13 by mask evaporation.

Next, the semiconductor layer 14 is formed according to the methods described above. In the following, two specific examples of the formation method of the semiconductor layer 14 are explained.

In the first method, first, appropriate amounts of (for example, equal weights of) inorganic semiconductor thin wires and organic semiconductor material are mixed in a solvent, and both are sufficiently dispersed in the solvent so as to be uniform, to thereby obtain a mixed solution. Examples of the solvent that may be used include chloroform, toluene, xylene, and mesitylene. The inorganic semiconductor thin wires may be formed by the foregoing methods. Next, this mixed solution is applied and dried, and thereby the semiconductor layer 14 (thickness of 500 nm, for example) is formed. The application of the mixed solution may be conducted by, for example, spin coating.

In the second method, first, inorganic semiconductor thin wires are dispersed in a dispersion medium to prepare a mixed solution. This mixed solution is applied at a desired location and thereafter dried (to remove the dispersion medium), to form a film of the inorganic semiconductor thin wires. Examples of the dispersion medium that may be used include ethanol, chloroform, toluene, xylene, and mesitylene. A solution containing an organic semiconductor material is applied to this film, followed by drying. Examples of the solution containing the organic semiconductor material that may be used include a solution obtained by dissolving an organic semiconductor material in a solvent such as chloroform, toluene, xylene, and mesitylene. The application of this solution causes the organic semiconductor material to be impregnated into the film of the inorganic semiconductor thin wires, and thereby the semiconductor layer 14 is formed that is a hybrid of the semiconductor thin wires and the organic semiconductor material.

### [Second Manufacturing Method]

In the following, one example of the manufacturing method of the FET 100d shown in FIG. 1D is described. First, a silicon oxide layer is formed on a surface of a silicon substrate, and thereafter, a source electrode and a drain electrode are formed. These electrodes can be formed of, for example, titanium. These electrodes can be formed by, for example, depositing a metal film by sputtering and thereafter patterning the film by a photolithography-etching process.

Next, inorganic semiconductor thin wires made of silicon are grown from the surfaces of the source electrode and the drain electrode by a CVD method. The source gas to be used may be silane or disilane. The catalyst for growing the semiconductor thin wires may be a catalyst of gold, for example.

By exposing only specific side faces of the surfaces of the source electrode and the drain electrode, specifically, only the side faces that oppose the other electrode, the inorganic semiconductor thin wires can be grown from these side faces. Portions other than the portions from which the inorganic semiconductor thin wires are to be grown are covered by a resist mask or the like. This method makes it possible to grow the inorganic semiconductor thin wires from one of the electrodes toward the other electrode so as to be parallel to the surface of the substrate.

Next, a solution containing an organic semiconductor material is applied over the source electrode, the drain electrode, and the inorganic semiconductor thin wires, and thereafter, the applied solution is dried. Next, the channel region portion is masked by a resist, and the portion of the organic semiconductor layer other than the channel region is removed by a photolithography-etching process. Thus, the semiconductor layer 14 is formed.

Next, the gate insulating layer 13 and the gate electrode 12 are formed on the semiconductor layer 14 by a known method. Thus, the FET 100d can be fabricated.

### [Third Manufacturing Method]

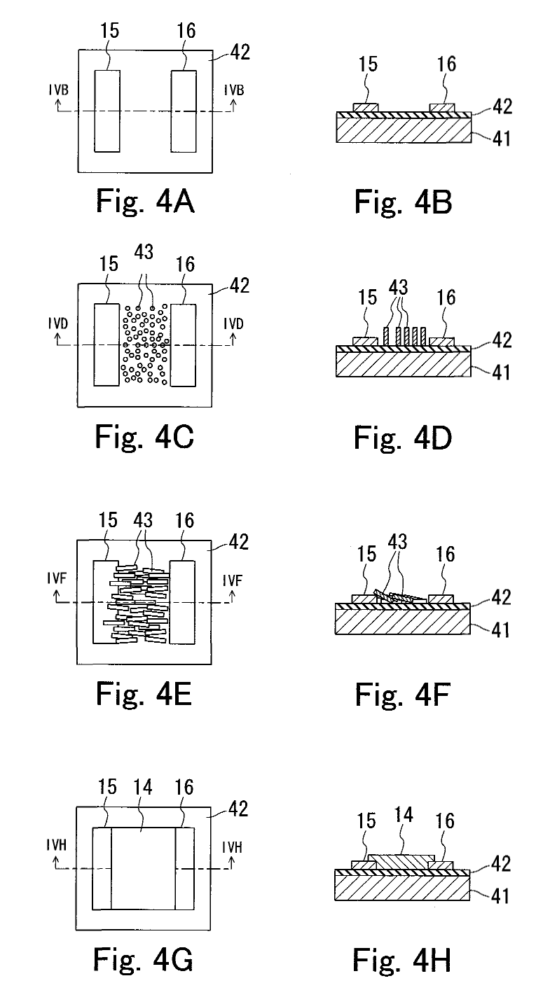

One example of the method of manufacturing a FET similar to the FET 100d is described with reference to FIGS. 4A to 4H. FIGS. 4A, 4C, 4E, and 4G show top views, and FIGS. 4B, 4D, 4F, and 4H show the respective cross-sectional views thereof.

First, a silicon oxide layer 42 is formed on a surface of a silicon substrate 41, and thereafter, a source electrode 15 and a drain electrode 16 are formed thereon (FIGS. 4A and 4B). These electrodes are formed in the same manner as in the second manufacturing method.

Next, inorganic semiconductor thin wires 43 made of silicon are grown on the surface of the silicon oxide layer 42 by a CVD method (FIGS. 4C and 4D). Silane is used as the source gas. Gold is used as the catalyst for growing the nanowires. These catalyst fine particles are disposed on the surface of the silicon oxide layer in the following method; a gold colloidal solution is spin-coated or a gold thin film is deposited by a sputtering method or an evaporation method on the surface of the silicon oxide layer, followed by annealing, to thereby form gold fine particles in a self-organizing manner.

In this method, the inorganic semiconductor thin wires 43 grow in the direction perpendicular to the substrate surface. Next, the grown inorganic semiconductor thin wires 43 are pushed down in a direction substantially parallel to the direction connecting the source electrode 15 and the drain electrode 16 (FIGS. 4E and 4F). This enables the inorganic semiconductor thin wires to be oriented approximately in the above-mentioned direction. The inorganic semiconductor thin wires 43 can be pushed down in one direction using, for example, rubbing equipment for forming alignment films of liquid crystal. In this way, a film of the inorganic semiconductor thin wires is formed.

Next, a solution containing an organic semiconductor material is applied over the source electrode 15, the drain electrode 16, and the inorganic semiconductor thin wires 43 by spin coating, and thereafter, the applied solution is dried. Next, a region in the vicinity of the channel region is masked by a resist, and the portion of the organic semiconductor layer other than the region in the vicinity of the channel region is removed by a photolithography-etching process. Thus, a semiconductor layer 14 is formed (FIGS. 4G and 4H).

Next, a gate insulating layer 13 and a gate electrode 12 are formed on the semiconductor layer 14 by a known method. Thus, the FET 100d can be fabricated.

### [Fourth Manufacturing Method]

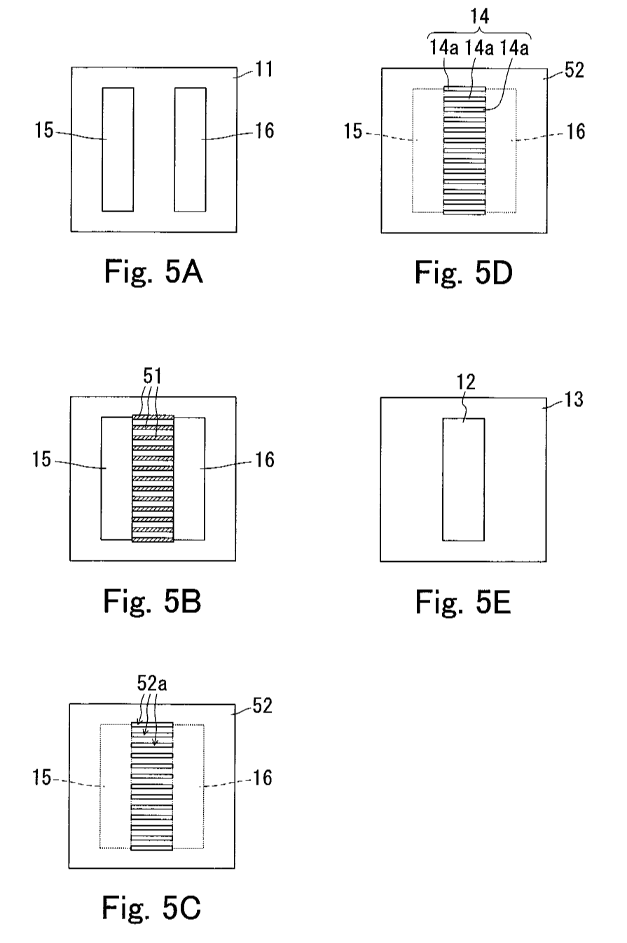

In the following, another example is described of the manufacturing method of the FET 100d shown in FIG. 1D. First, as illustrated in FIG. 5A, a source electrode 15 and a drain electrode 16 are formed on the surface of a substrate 11. These electrodes are formed in the same manner as in the second manufacturing method.

Next, as illustrated in FIG. 5B, a resist film 51 (hatched in FIG. 5B) is formed. The resist film 51 is formed in stripes between the source electrode 15 and the drain electrode 16. The resist film 51 can be formed using, for example, a photoresist (OFPR5000) made by Tokyo Ohka Kogyo Co., Ltd.

Next, an oil repellent film is formed over the entire surface of the substrate so as to cover the resist film 51, and thereafter the resist film 51 is removed. Thus, as illustrated in FIG. 5C, an oil repellent film 52 having a plurality of band-shaped through holes 52a is formed. The through holes 52a are formed in stripes between the source electrode 15 and the drain electrode 16. The oil repellent film can be formed, for example, in the following manner. First, the substrate is immersed in a solution of a monomolecular film-forming material (X-24-9367C) made by Shin-Etsu Chemical Co., Ltd., for 2 minutes within a glove box in a dry atmosphere. Thereafter, the substrate is rinsed using a cleaning solution (for example, Hydro Fluoro Ether HEF-7200 made by Sumitomo 3M Limited) in the glove box. Thus, the oil repellent film can be formed. Each of the band-shaped through holes 52a extends in the direction connecting the source electrode 15 and the drain electrode 16 and has a width of about 0.5 μm to about 5 μm. The gap between the through holes 52a is, for example, about 0.5 μm to about 10 μm.

Next, as illustrated in FIG. 5D, a semiconductor layer 14 including a plurality of band-shaped semiconductor layers 14a is formed. The semiconductor layer 14 can be formed in the above-described method. When a solution in which inorganic semiconductor thin wires are dispersed is applied onto the oil repellent film 52, the solution is repelled by the oil repellent film 52 because the oil repellent film 52 has been formed between the source electrode 15 and the drain electrode 16, and the solution is disposed only within the band-shaped through holes 52a. The inorganic semiconductor thin wires disposed within the through holes 52a are oriented in the direction connecting the source electrode 15 and the drain electrode 16. Thereafter, a solution containing an organic semiconductor is applied and dried in the same manner as in the second manufacturing method, and thereby a semiconductor layer 14 is formed in stripes.

Next, a gate insulating layer 13 and a gate electrode 12 are formed on the semiconductor layer 14 by a known method (FIG. 5E). Thus, the FET 100d can be fabricated.

It should be noted that the FET 100a and the FET 100c can be formed likewise in similar manners to those for the FET 100b and the FET 100d by merely changing the order of formation of the components. For example, in the case of the FET 100a, the gate electrode 12, the gate insulating layer 13, the semiconductor layer 14, and the source electrode 15 and the drain electrode 16 should be formed on top of the substrate 11 in that order. In the case of the FET 100c, the semiconductor layer 14, the source electrode 15 and the drain electrode 16, the gate insulating layer 13, and the gate electrode 12 should be formed on top of the substrate 11 in that order.

### Embodiment 2

Embodiment 2 describes an active matrix-type display, a wireless ID tag, and portable devices as examples of an electronic device equipped with the FET that has been described in Embodiment 1 according to the present invention.

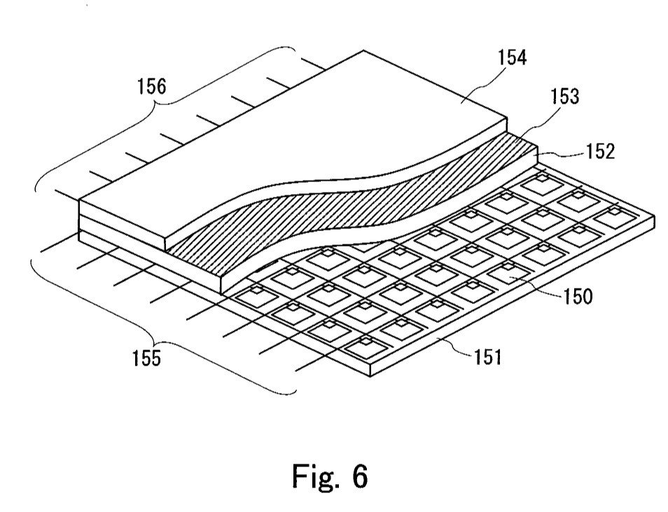

A display using an organic EL for the display unit will be described as one example of the active matrix-type display. FIG. 6 shows a partially exploded perspective view schematically illustrating the configuration of the display.

The display illustrated in FIG. 6 has a driving circuit 150 disposed on a plastic substrate 151 in an array form. The driving circuit 150 includes the FETs according to the present invention, and is connected to pixel electrodes. An organic EL layer 152, a transparent electrode 153, and a passivation film 154 are disposed above the driving circuit 150. The organic EL layer 152 has a structure in which a plurality of layers are stacked, such as an electron transport layer, a light-emitting layer, and a hole transport layer. Source lines 155 and gate lines 156 connected to the electrodes of the FETs are connected respectively to a control circuit (not shown).

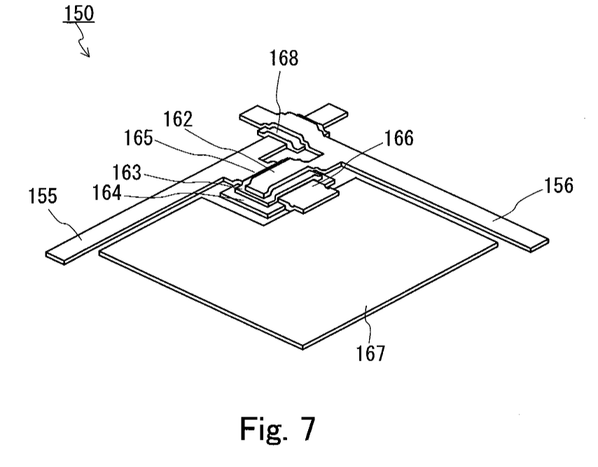

FIG. 7 illustrates an enlarged view of one example of the driving circuit 150 and its periphery. Basically, the structure of the FET shown in FIG. 7 is basically the same as the structure of the FET 100c shown in FIG. 1C. In the FET shown in FIG. 7, a semiconductor layer 164, a source electrode 165 and a drain electrode 166, a gate insulating layer 163, and a gate electrode 162 are stacked on top of the substrate. The drain electrode 166 is connected electrically to a pixel electrode 167 of the organic EL. In addition, an insulating layer 168 is formed at a portion at which a gate line 156, to which the gate electrode 162 is connected, intersects with a source line 155, to which the source electrode 165 is connected. The foregoing semiconductor layer 14 is used as the semiconductor layer 164.

Thus, FETs with high carrier mobility and small variations in threshold voltage can be realized stably by configuring an active matrix-type display utilizing the FET described in Embodiment 1. This makes it possible to obtain a high-performance, low-cost display. Moreover, using the FET according to the present invention, a sheet-like display having flexibility and shock resistance can be realized. Furthermore, due to the improvement in carrier mobility, it becomes possible to obtain an active matrix-type display with fast display speed (response speed).

It should be noted that although this embodiment has discussed a case that uses an organic EL for the display unit, the present invention is not limited thereto. The present invention is applicable to other active matrix-type displays equipped with circuits containing FETs, and thereby the same advantageous effects will result.

In addition, the configuration of the driving circuit unit for driving pixels is not limited to the configuration shown in this embodiment. For example, it is possible to employ a configuration in which a current driving FET and a switching FET for controlling the current driving FET are combined to drive one pixel. Moreover, it is possible to employ a configuration in which a further plurality of FETs is combined therewith. Furthermore, in place of the FET shown in FIG. 7, other FETs according to the present invention may be employed, and the same advantageous effects can be attained likewise in such cases.

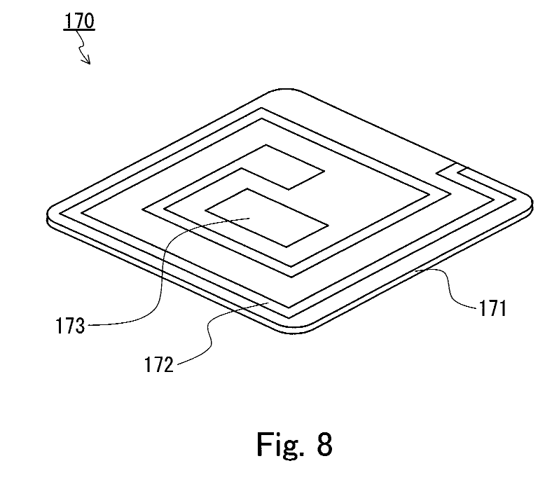

Next, a case in which the FET according to the present invention is applied to a wireless ID tag will be described. FIG. 8 schematically illustrates a perspective view of one example of the wireless ID tag that utilizes the FET according to the present invention.

A wireless ID tag 170 employs a film-like plastic substrate 171 as its substrate. An antenna unit 172 and a memory IC unit 173 are provided on this substrate 171. Here, the memory IC unit 173 is configured utilizing the FET according to the present invention described in Embodiment 1. The back side of the substrate of the wireless ID tag 170 is provided with an adhesive function so that it can be adhered onto items that are not flat, such as bags for confectionery or snack items or beverage cans. Additionally, a passivation film is provided on the surface of the wireless ID tag 170 as necessary.

Thus, using the FET according to the present invention makes it possible to obtain wireless ID tags having various shapes and being capable of adhering to items made of various materials. Moreover, the use of the FET according to the present invention, which has high carrier mobility, enables wireless ID tags having fast response speed (processing speed) and high communication frequency to be obtained.

It should be noted that the wireless ID tag according to the present invention is not limited to the wireless ID tag as shown in FIG. 8. Accordingly, there are no restrictions to the arrangements and configurations of the antenna unit and the memory IC unit. For example, it is possible to incorporate a moral circuit into the wireless ID tag.

Furthermore, although this embodiment has discussed a case in which the antenna unit 172 and the memory IC unit 173 are formed on the plastic substrate 171, the present invention is not limited to this embodiment. For example, the antenna unit 172 and the memory IC unit 173 may be directly formed on a target object by using such a method as ink jet printing. In that case as well, by forming the FET according to the present invention, it becomes possible to manufacture a wireless ID tag having a FET with improved carrier mobility and threshold voltage at low cost.

Next, portable devices provided with an integrated circuit including the FET according to the present invention will be described. Various elements that utilize the properties of semiconductor, such as arithmetic elements, memory elements, and switching elements, are used in the integrated circuit of the portable devices. Using the FET according to the present invention for at least a portion of these elements makes it possible to manufacture portable devices that are excellent in such characteristics as mechanical flexibility, shock resistance, safety to environment at disposal, being lightweight, and being low-cost, which are the advantages of organic materials.

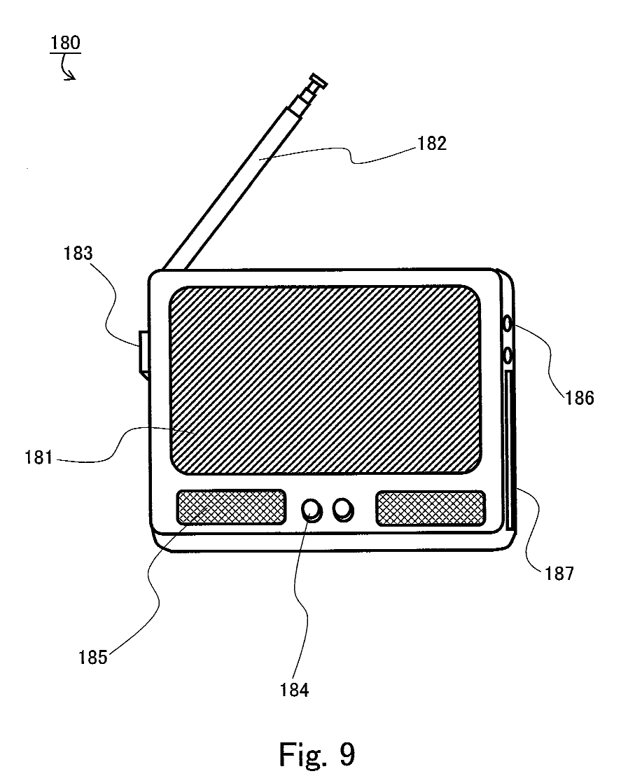

FIGS. 9 to 11 illustrate three types of mobile devices as examples of the portable electronic devices according to the present invention. A portable television 180 shown in FIG. 9 is furnished with a display device 181, a receiver device 182, side switches 183, front switches 184, an audio output unit 185, an input/output device 186, and a recording media insertion unit 187. The integrated circuit containing the FET according to the present invention is used as a circuit that contains such elements as arithmetic elements, memory elements, and switching elements that constitute the portable television 180.

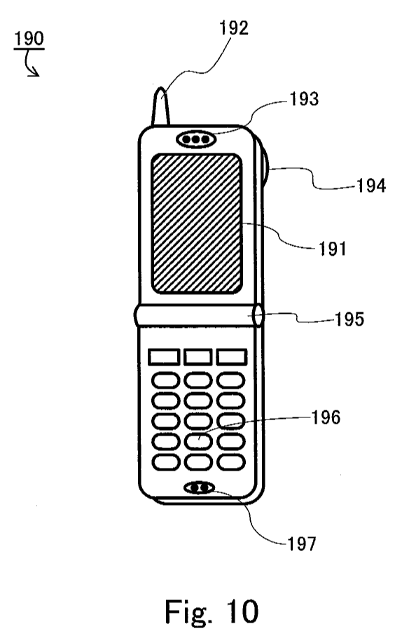

A communication terminal 190 shown in FIG. 10 is furnished with a display device 191, a transceiver device 192, an audio output unit 193, a camera unit 194, a movable hinge joint part 195, control buttons 196, and an audio input unit 197. The integrated circuit containing the FET according to the present invention is used as a circuit that contains such elements as arithmetic elements, memory elements, and switching elements that constitute the communication terminal 190.

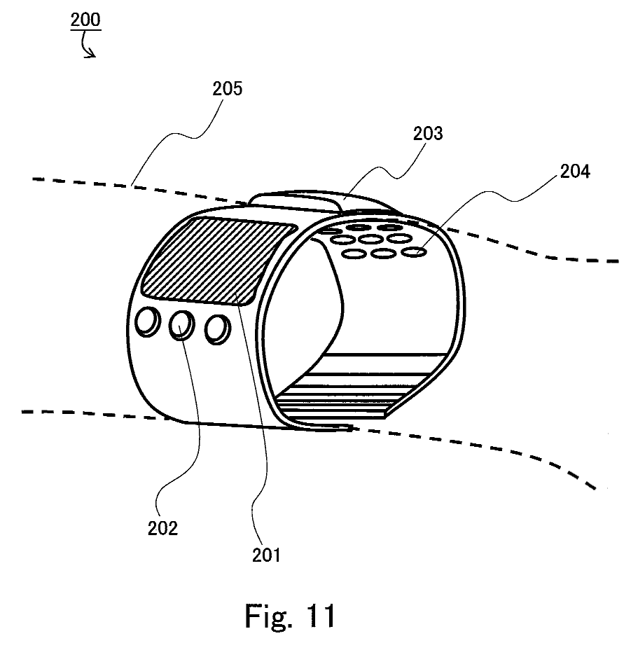

A portable medical device 200 shown in FIG. 11 is furnished with a display device 201, control buttons 202, a medical treatment unit 203, and percutaneous contact portions 204. The portable medical device 200 may be carried about while being wrapped around a human arm 205. The medical treatment unit 203 is a part that processes biometric information obtained through the percutaneous contact portions 204 and performs medical treatments such as providing drugs through the percutaneous contact portions 204. The integrated circuit containing the FET according to the present invention is used as a circuit that contains such elements as arithmetic elements, memory elements, and switching elements that constitute the portable medical device 200.

Although the configurations of the electronic devices to which the FET according to the present invention is applied have been illustrated referring to the examples, the present invention is not limited to these configurations. Moreover, the electronic devices to which the FET according to the present invention can be applied are not limited to the devices illustrated above. The FET according to the present invention can be applied suitably to various devices such as PDA terminals, wearable AV devices, portable computers, and wrist watch-type communication devices, which require such characteristics as mechanical flexibility, shock resistance, safety to environment at disposal, being lightweight, and being low-cost.

While embodiments of the present invention have been illustrated referring to the examples thereof, it should be understood that the present invention is not limited to the embodiments described above, but may be applied to various other embodiments based on the technical idea of the present invention.

### INDUSTRIAL APPLICABILITY

The present invention is applicable to field-effect transistors, and various electronic devices provided with the field-effect transistors.

1. A field effect transistor comprising:
a semiconductor layer, a source electrode and a drain electrode electrically connected to the semiconductor layer, a gate electrode for applying an electric field to the semiconductor layer,
the semiconductor layer comprising an organic semiconductor material and a plurality of thin wires made of an inorganic semiconductor.

2. The field-effect transistor according to claim 1, wherein the thin wires are connected to at least one electrode selected from the group consisting of the source electrode and the drain electrode via the organic semiconductor material.

3. The field-effect transistor according to claim 1, wherein both the organic semiconductor material and the thin wires function as a p-type semiconductor.

4. The field-effect transistor according to claim 1, wherein the semiconductor layer is formed in stripes parallel to a direction connecting the source electrode and the drain electrode.

5. The field-effect transistor according to claim 1, wherein an average diameter of the thin wires is 100 nm or less.

6. The field-effect transistor according to claim 1, wherein the thin wires are oriented in a direction connecting the source electrode and the drain electrode.

7. The field-effect transistor according to claim 1, wherein the thin wires are grown from at least one electrode selected from the group consisting of the source electrode and the drain electrode.

8. An electronic device comprising a substrate and a transistor formed on the substrate, wherein
the transistor is a field-effect transistor according to claim 1.

9. The electronic device according to claim 8, wherein the substrate is made of a polymer material.

10. The electronic device according to claim 8, wherein the device is an active matrix-type display.

11. The electronic device according to claim 8, wherein the device is a wireless ID tag.

12. The electronic device according to claim 8, wherein the device is a portable device.

13. A method of manufacturing a field-effect transistor comprising a substrate, a semiconductor layer formed on the substrate, a source electrode and a drain electrode electrically connected to the semiconductor layer, the method comprising the steps of:
(i) growing on the substrate a plurality of thin wires made of an inorganic semiconductor;
(ii) laying down the thin wires in a direction connecting the source electrode and the drain electrode; and
(iii) impregnating space between the laid-down thin wires with an organic semiconductor material.
